(19) United States
(12) Patent Application Publication
(10) Pub. No.: US 2026/0096115 A1
(43) Pub. Date: Apr. 2, 2026

(54) SEMICONDUCTOR DEVICE

(71) Applicant: Mitsubishi Electric Corporation, Tokyo (JP)

(72) Inventors: Kohei SAKO, Tokyo (JP); Kakeru OTSUKA, Tokyo (JP); Kazuya KONISHI, Tokyo (JP)

(73) Assignee: Mitsubishi Electric Corporation, Tokyo (JP)

(21) Appl. No.: 19/290,314

(22) Filed: Aug. 4, 2025

(30) Foreign Application Priority Data
Sep. 30, 2024 (JP) 2024-169769

(51) Int. Cl. H10D 12/00; H10D 62/10; H10D 64/00; H10D 64/27

(52) U.S. Cl. CPC H10D 12/415; H10D 12/481; H10D 62/103; H10D 64/117; H10D 64/516; H10D 64/518

(57) ABSTRACT

A semiconductor device according to the present disclosure includes: a trench located in a semiconductor substrate on a side of a front surface thereof to extend through a base layer, the trench including a top electrode covered with a top oxide film, a bottom electrode covered with a bottom oxide film, and a boundary oxide film located between the top electrode and the bottom electrode, wherein a surface of the top electrode facing the bottom electrode has a recessed shape and includes a prong forming the recessed shape, the prong extends in a width direction of the trench, the prong and the bottom electrode face each other in the width direction of the trench, the top oxide film has a constant film thickness along the base layer and a layer underlying the base layer, and the boundary oxide film has a greater film thickness than the top oxide film.

### BACKGROUND

### Technical Field

The present disclosure relates to a semiconductor device in which conduction is controlled by a gate signal.

### Description of the Background Art

A semiconductor device including a gate structure including a top electrode and a bottom electrode has been disclosed (see Japanese Patent Application Laid-Open No. 2017-45776, for example).

In the gate structure including the top electrode and the bottom electrode, a portion of the top electrode facing the bottom electrode has a prong. An electric field is high at the prong, so that a problem of reduction in gate breakdown voltage arises due to an increase in gate leakage.

In Japanese Patent Application Laid-Open No. 2017-45776, an electric field mitigating portion is located adjacent to the prong of the top electrode. The electric field mitigating portion is a thick oxide film including two layers including a thermal oxide film and a chemical vapor deposition (CVD) film. Thus, at an interface between the prong and a semiconductor layer via the electric field mitigating layer, holes are less likely to be stored, and a saturation voltage Vce (sat) cannot be reduced.

### SUMMARY

It is an object of the present disclosure to provide a semiconductor device in which a saturation voltage can be reduced while a gate breakdown voltage is improved.

A semiconductor device according to the present disclosure includes: a semiconductor substrate; a base layer of a first conductivity type located in the semiconductor substrate on a side of a front surface thereof; a trench located in the semiconductor substrate on the side of the front surface thereof to extend through the base layer, the trench including a top electrode covered with a top oxide film, a bottom electrode covered with a bottom oxide film, and a boundary oxide film located between the top electrode and the bottom electrode, wherein a surface of the top electrode facing the bottom electrode has a recessed shape and includes a prong forming the recessed shape, the prong extends in a width direction of the trench, the prong and the bottom electrode face each other in the width direction of the trench, the top oxide film has a constant film thickness along the base layer and a layer underlying the base layer, and the boundary oxide film has a greater film thickness than the top oxide film.

According to the present disclosure, a saturation voltage can be reduced while a gate breakdown voltage is improved.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a cross-sectional view of a semiconductor device according to Embodiment 1;

FIG. 2 is a cross-sectional view of the semiconductor device according to Embodiment 1;

FIG. 3 is a cross-sectional view of a semiconductor device according to Modification 1;

FIG. 4 is a cross-sectional view of a semiconductor device according to Modification 2; and

FIG. 5 is a cross-sectional view of a semiconductor device according to Modification 5.

### DESCRIPTION OF THE PREFERRED EMBODIMENTS

### Embodiment 1

A semiconductor device according to Embodiment 1 will be described below with reference to the drawings. The same or corresponding components bear the same reference signs, and repeated description is sometimes omitted. In description made below, N and P indicate conductivity types of a semiconductor. In the present disclosure, description will be made with a first conductivity type as a P type and a second conductivity type as an N type. These conductivity types may be reversed.

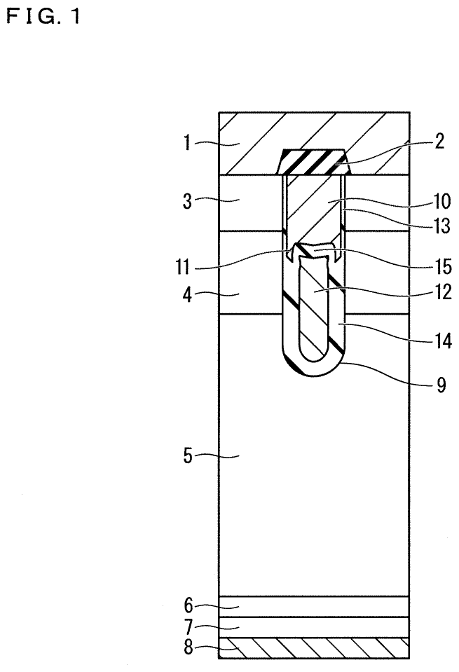

FIG. 1 is a cross-sectional view of a semiconductor device according to Embodiment 1. In FIG. 1, a semiconductor substrate is in a range from a base layer 3 to a collector layer 7. In FIG. 1, an upper end of the base layer 3 is referred to as a front surface of the semiconductor substrate, and a lower end of the collector layer 7 is referred to as a back surface of the semiconductor substrate. The front surface and the back surface face each other. While description will be made below with the semiconductor device as an insulated gate bipolar transistor (IGBT), the semiconductor device is not limited to the IGBT. The semiconductor device may be a reverse conducting IGBT (RC-IGBT), for example.

As illustrated in FIG. 1, on a side of the front surface of an N-type drift layer 5, an N-type carrier storage layer 4 having a higher N-type impurity concentration than the drift layer 5 is provided. The semiconductor device may have a configuration in which the carrier storage layer 4 is not provided. In this case, the drift layer 5 is to be provided also in a region of the carrier storage layer 4 illustrated in FIG. 1.

The P-type base layer 3 is provided on a side of the front surface of the carrier storage layer 4.

The semiconductor substrate has a trench 9 extending through the base layer 3 and the carrier storage layer 4 to the drift layer 5. The trench 9 includes therein a top electrode 10 as a gate potential in a top portion and a bottom electrode 12 as an emitter potential in a bottom portion. The top electrode 10 may be the emitter potential, and the bottom electrode 12 may be the gate potential.

The top electrode 10 is covered with a top oxide film 13, and the bottom electrode 12 is covered with a bottom oxide film 14. The top oxide film 13 has a constant film thickness along the base layer 3 and the carrier storage layer 4. That is to say, the top oxide film 13 has a constant film thickness along a side surface of the top electrode 10.

The trench 9 includes a boundary oxide film 15 located between the top electrode 10 and the bottom electrode 12. The top electrode 10 and the bottom electrode 12 are electrically separated from each other via the boundary oxide film 15. The boundary oxide film 15 has a greater film thickness than the top oxide film 13.

A surface of the top electrode 10 facing the bottom electrode 12 has a recessed shape and includes a prong 11 forming the recessed portion. The prong 11 and the bottom electrode 12 face each other in a width direction of the trench 9 (a direction perpendicular to a direction connecting the front surface and the back surface).

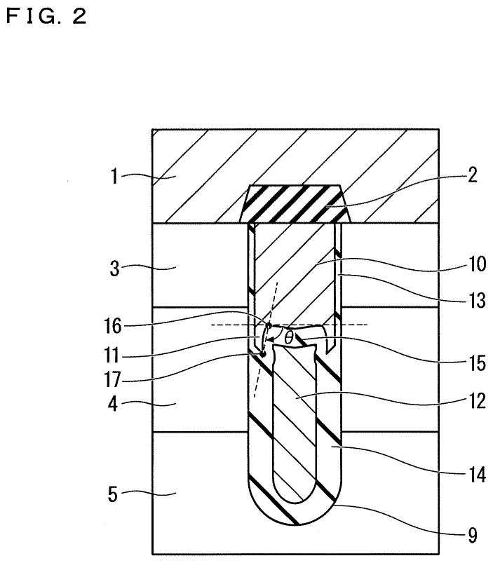

The prong 11 extends in the width direction of the trench 9 (extend outward of the trench 9) and has a curved inner surface. Specifically, the prong 11 includes a root 16 and a tip 17 as illustrated in FIG. 2. A straight line in the width direction of the trench 9 passing through the root 16 and a straight line connecting the root 16 and the tip 17 form an angle θ of greater than 90° (90°<θ). The angle θ may satisfy a formula 90°<θ≤135°. A buffer layer 6, the collector layer 7, and a collector electrode 8 are not illustrated in FIG. 2.

Referring back to FIG. 1, an interlayer insulating film 2 is provided over the trench 9. An emitter electrode 1 is provided over the base layer 3 and the interlayer insulating film 2.

On a side of the back surface of the drift layer 5, the N-type buffer layer 6 having a higher N-type impurity concentration than the drift layer 5 is provided. The P-type collector layer 7 is provided on a side of the back surface of the buffer layer 6. The collector electrode 8 is provided on a side of the back surface of the collector layer 7.

According to Embodiment 1, the prong 11 of the top electrode 10 extends in the width direction of the trench 9, so that a distance between the top electrode 10 and the bottom electrode 12 can be ensured to improve a gate breakdown voltage.

The top oxide film 13 has a constant film thickness along the base layer 3 and the carrier storage layer 4, so that, at an interface of the carrier storage layer 4 facing the prong 11 (an interface between the trench 9 and the carrier storage layer 4), an N-type storage layer is formed, and holes are likely to be stored. A saturation voltage Vce (sat) can thus be reduced.

Furthermore, the boundary oxide film 15 has a greater film thickness than the top oxide film 13, so that insulation between the top electrode 10 and the bottom electrode 12 can be improved.

### Modification 1

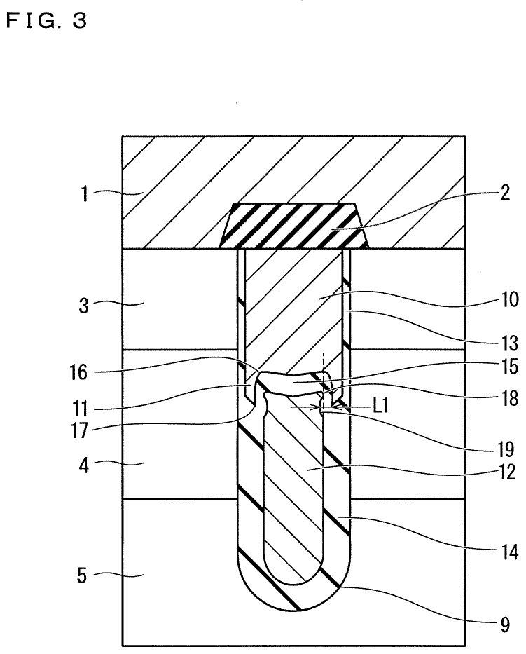

FIG. 3 is a cross-sectional view of a semiconductor device according to Modification 1. As illustrated in FIG. 3, a side surface (a side surface on each of opposite left and right sides) of the bottom electrode 12 includes a recess 19 recessed inward of a corner 18 of the bottom electrode 12 on a side of the front surface. The tip 17 of the prong 11 and the recess 19 face each other in the width direction of the trench 9. The buffer layer 6, the collector layer 7, and the collector electrode 8 are not illustrated in FIG. 3.

According to Modification 1, the bottom electrode 12 includes the recess 19, so that a distance L1 between the top electrode 10 and the bottom electrode 12 can be increased. The gate breakdown voltage can thus be improved.

### Modification 2

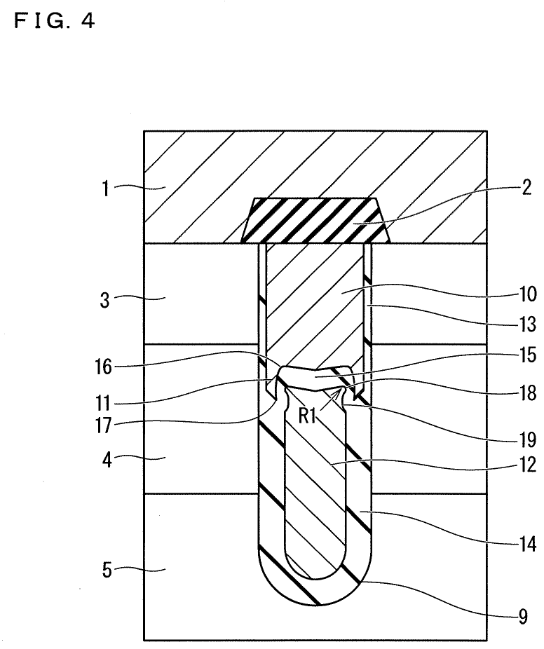

FIG. 4 is a cross-sectional view of a semiconductor device according to Modification 2. As illustrated in FIG. 4, the corner 18 of the bottom electrode 12 on the side of the front surface has curvature R1. That is to say, the corner 18 is rounded. The buffer layer 6, the collector layer 7, and the collector electrode 8 are not illustrated in FIG. 4.

According to Modification 2, the corner 18 of the bottom electrode 12 has the curvature R1, so that an electric field concentration at the corner 18 can be mitigated. The gate breakdown voltage can thus be improved.

### Modification 3

In a semiconductor device according to Modification 3, the top oxide film 13 includes two layers including a thermal oxide film and a CVD film. Specifically, the thermal oxide film is provided along an inner wall of the trench 9, and the CVD film is provided over the thermal oxide film.

According to Modification 3, the thermal oxide film is used, so that curvature can be imparted to the corner 18 of the bottom electrode 12 due to enhanced oxidation. The CVD film is used, so that the prong 11 of the top electrode 10 can be extended in the width direction of the trench 9, and thus the distance between the top electrode 10 and the bottom electrode 12 can be ensured. That is to say, the thermal oxide film and the CVD film are included, so that the gate breakdown voltage can be improved.

The top oxide film 13 as a whole includes the two layers, so that there is no portion connecting the layers as in a configuration in which a top oxide film includes both a portion including a single layer and a portion including two layers (see Japanese Patent Application Laid-Open No. 2017-45776, for example). Local electric field concentration can thus be prevented.

### Modification 4

In a semiconductor device according to Modification 4, the top oxide film 13 includes three layers including a first thermal oxide film, a CVD film, and a second thermal oxide film. Specifically, the first thermal oxide film is provided along the inner wall of the trench, the CVD film is provided over the first thermal oxide film, and the second thermal oxide film is provided over the CVD film.

According to Modification 4, the first thermal oxide film is used, so that curvature can be imparted to the corner 18 of the bottom electrode 12 due to enhanced oxidation. The CVD film is used, so that the prong 11 of the top electrode 10 can be extended in the width direction of the trench 9, and thus the distance between the top electrode 10 and the bottom electrode 12 can be ensured. While a variation in film thickness of the CVD film increases in a process of the semiconductor device, the variation of the CVD film can be suppressed by providing the second thermal oxide film over the CVD film. That is to say, the first thermal oxide film, the CVD film, and the second thermal oxide film are included, so that the gate breakdown voltage can be improved.

Local electric field concentration can be prevented as in Modification 3.

### Modification 5

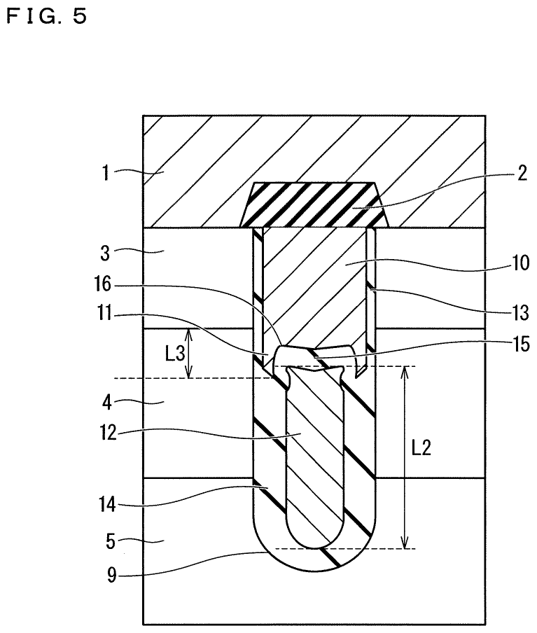

FIG. 5 is a cross-sectional view of a semiconductor device according to Modification 5. As illustrated in FIG. 5, a length L2 of the bottom electrode 12 is greater than a length L3 of a portion of the top electrode 10 protruding from the base layer 3 toward the back surface. The buffer layer 6, the collector layer 7, and the collector electrode 8 are not illustrated in FIG. 5.

Layers underlying the base layer 3 are of the N type, so that an electric field is likely to increase. According to Modification 5, an N-type region facing the bottom electrode 12 (a region including the carrier storage layer 4 and the drift layer 5 in an example of FIG. 5) is set to be larger than an N-type region facing the top electrode 10 (a region including the carrier storage layer 4 in the example of FIG. 5), so that an electric field can be mitigated by a field plate effect.

Embodiments can freely be combined with each other and can be modified or omitted as appropriate within the scope of the present disclosure.

### Appendices Various aspects of the present disclosure will collectively be described below as appendices.

### Appendix 1

A semiconductor device comprising:
a semiconductor substrate;
a base layer of a first conductivity type located in the semiconductor substrate on a side of a front surface thereof;
a trench located in the semiconductor substrate on the side of the front surface thereof to extend through the base layer, the trench including a top electrode covered with a top oxide film, a bottom electrode covered with a bottom oxide film, and a boundary oxide film located between the top electrode and the bottom electrode, wherein
a surface of the top electrode facing the bottom electrode has a recessed shape and includes a prong forming the recessed shape,
the prong extends in a width direction of the trench,
the prong and the bottom electrode face each other in the width direction of the trench,
the top oxide film has a constant film thickness along the base layer and a layer underlying the base layer, and
the boundary oxide film has a greater film thickness than the top oxide film.

### Appendix 2

The semiconductor device according to Appendix 1, wherein
the prong includes a root and a tip, and
a straight line in the width direction of the trench passing through the root and a straight line connecting the root and the tip form an angle of greater than 90°.

### Appendix 3

The semiconductor device according to Appendix 1 or 2, wherein
a side surface of the bottom electrode includes a recess recessed inward of a corner of the bottom electrode on the side of the front surface.

### Appendix 4

The semiconductor device according to any one of Appendices 1 to 3, wherein
a corner of the bottom electrode on the side of the front surface has curvature.

### Appendix 5

The semiconductor device according to any one of Appendices 1 to 4, wherein
the top oxide film includes two layers including a thermal oxide film and a chemical vapor deposition (CVD) film.

### Appendix 6

The semiconductor device according to any one of Appendices 1 to 4, wherein
the top oxide film includes three layers including a first thermal oxide film, a CVD film, and a second thermal oxide film.

### Appendix 7

The semiconductor device according to any one of Appendices 1 to 6, wherein
the bottom electrode has a greater length than a portion of the top electrode protruding from the base layer toward a back surface.

While the disclosure has been shown and described in detail, the foregoing description is in all aspects illustrative and not restrictive. It is therefore understood that numerous modifications and variations can be devised.

What is claimed is:

1. A semiconductor device comprising:
a semiconductor substrate;
a base layer of a first conductivity type located in the semiconductor substrate on a side of a front surface thereof;
a trench located in the semiconductor substrate on the side of the front surface thereof to extend through the base layer, the trench including a top electrode covered with a top oxide film, a bottom electrode covered with a bottom oxide film, and a boundary oxide film located between the top electrode and the bottom electrode, wherein
a surface of the top electrode facing the bottom electrode has a recessed shape and includes a prong forming the recessed shape,
the prong extends in a width direction of the trench,
the prong and the bottom electrode face each other in the width direction of the trench,
the top oxide film has a constant film thickness along the base layer and a layer underlying the base layer, and
the boundary oxide film has a greater film thickness than the top oxide film.

2. The semiconductor device according to claim 1, wherein
the prong includes a root and a tip, and
a straight line in the width direction of the trench passing through the root and a straight line connecting the root and the tip form an angle of greater than 90°.

3. The semiconductor device according to claim 1, wherein
a side surface of the bottom electrode includes a recess recessed inward of a corner of the bottom electrode on the side of the front surface.

4. The semiconductor device according to claim 1, wherein
a corner of the bottom electrode on the side of the front surface has curvature.

5. The semiconductor device according to claim 1, wherein
the top oxide film includes two layers including a thermal oxide film and a chemical vapor deposition (CVD) film.

6. The semiconductor device according to claim 1, wherein
the top oxide film includes three layers including a first thermal oxide film, a CVD film, and a second thermal oxide film.

7. The semiconductor device according to claim 1, wherein
the bottom electrode has a greater length than a portion of the top electrode protruding from the base layer toward a back surface.
